(19) United States
(12) Patent Application Publication
(10) Pub. No.: US 2018/0233612 A1
(43) Pub. Date: Aug. 16, 2018

(54) THIN-FILM COMPOUND PHOTOVOLTAIC CELL, METHOD FOR MANUFACTURING THIN-FILM COMPOUND PHOTOVOLTAIC CELL, THIN-FILM COMPOUND PHOTOVOLTAIC CELL ARRAY, AND METHOD FOR MANUFACTURING THIN-FILM COMPOUND PHOTOVOLTAIC CELL ARRAY

(71) Applicant: SHARP KABUSHIKI KAISHA, Sakai City, Osaka (JP)

(72) Inventor: TATSUYA TAKAMOTO, Sakai City (JP)

(21) Appl. No.: 15/761,903

(22) PCT Filed: Sep. 15, 2016
(86) PCT No.: PCT/JP2016/077309

§ 371 Date: Mar. 21, 2018

(30) Foreign Application Priority Data
Sep. 28, 2015 (JP) 2015-189365

(51) Int. Cl. H01L 31/0468; H01L 31/0224; H01L 31/18

(52) U.S. Cl. CPC H01L 31/0468; H01L 31/18; H01L 31/0224

(57) ABSTRACT

A thin-film compound photovoltaic cell includes a cell body including a photovoltaic cell stack including a plurality of compound semiconductor layers, first and second electrodes that are formed on a first surface of the photovoltaic cell stack, the first surface being on a light receiving side of the photovoltaic cell stack, and a third electrode that is formed on a surface of the photovoltaic cell stack that is opposite to the light receiving side; and a resin film formed on the cell body, the resin film being formed on the side opposite to the light receiving side. The photovoltaic cell stack includes a cell layer including a PN junction layer and a contact layer that is formed on part of a surface of the cell layer which surface is opposite to a light-receiving surface of the cell layer. The third electrode is formed on the contact layer.

### TECHNICAL FIELD

This application claims the benefit of priority from Japanese Patent Application 2015-189365 filed on Sep. 28, 2015, the entire contents of which are incorporated herein by reference.

The present invention relates to a thin-film compound photovoltaic cell, to a method for manufacturing the thin-film compound photovoltaic cell, to a thin-film compound photovoltaic cell array, and to a method for manufacturing the thin-film compound photovoltaic cell array.

### BACKGROUND ART

In a conventional thin-film compound photovoltaic cell manufacturing method, a substrate is removed by etching or epitaxial lift-off.

A process including removal of a substrate by etching is disclosed in, for example, Japanese Patent No. 5554772 (PTL 1). In PTL 1, a cell body including a plurality of compound semiconductor layers is formed on the substrate, and a back electrode is formed on the cell body. Then a back film serving as a base is formed on the back electrode, and a reinforcing material is attached to the back film. Then the substrate is separated from the cell body.

In epitaxial lift-off, a sacrificial layer is formed between a substrate and a compound semiconductor layer, and an etchant is used to remove the sacrificial layer to thereby separate the compound semiconductor layer from the substrate. Examples of the epitaxial lift-off process are disclosed in Japanese Unexamined Patent Application Publication (Translation of PCT Application) No. 2014-523132 (PTL 2) and Japanese Patent No. 5576243 (PTL 3).

A method described in PTL 2 performs an epitaxial lift-off process including: growing at least one first protection layer on a first substrate; growing an AlAs layer; growing at least one second protection layer; depositing at least one active photovoltaic cell layer on the second protection layer; coating a top portion of the active photovoltaic cell layer with a metal; coating a second substrate with a metal; pressing together the two metal surfaces to form a cold-weld bond; and removing the AlAs layer by selective chemical etching. A thin-film III-V compound photovoltaic cell fabrication method described in PTL 3 includes the steps of: forming a metal backing layer on an active layer, the metal backing layer being in direct contact with the active layer; and removing the sacrificial layer from between the active layer and the substrate to separate the thin film III-V compound photovoltaic cell from the substrate.

### CITATION LIST

### Patent Literature

PTL 1: Japanese Patent No. 5554772

PTL 2: Japanese Unexamined Patent Application Publication (Translation of PCT Application) No. 2014-523132

PTL 3: Japanese Patent No. 5576243

### SUMMARY OF INVENTION

### Technical Problem

The back electrode in PTL 1 is formed over the entire surface of the cell body. The cold-weld bonded metal layer in PTL 2 is formed over the entire top portion of the active photovoltaic cell layer. The metal backing layer in PTL 3 is formed over the entire surface of the active layer. Therefore, in the structures of the photovoltaic cells manufactured by the above methods, light is not transmitted to the side opposite to a light receiving surface.

Therefore, disadvantageously, the methods described in PTL 1, PTL 2, and PTL 3 are not applicable to manufacturing of a double-sided light receiving photovoltaic cell and an upper photovoltaic cell of a mechanical stack.

The present invention has been made in view of the above circumstances, and an object of the invention is to provide a thin-film compound photovoltaic cell and a thin-film compound photovoltaic cell array that allow light to be transmitted to the side opposite to their light-receiving surface.

### Solution to Problem

To achieve the above object of the present invention, a thin-film compound photovoltaic cell thin-film compound photovoltaic cell comprises: a cell body including a photovoltaic cell stack including a plurality of compound semiconductor layers, a first electrode that has a first polarity and is formed on part of a first surface of the photovoltaic cell stack, the first surface being on a light receiving side of the photovoltaic cell stack, a second electrode that has a second polarity and is formed on a second surface of the photovoltaic cell stack, the second surface being on the light receiving side of the photovoltaic cell stack and being different from the first surface, and a third electrode that has the second polarity and is formed on part of a surface of the photovoltaic cell stack which surface is on a side opposite to the light receiving side of the photovoltaic cell stack; and a resin film formed on the cell body, the resin film being formed on a side opposite to a light receiving side of the cell body, wherein the photovoltaic cell stack includes a cell layer and a contact layer, the cell layer including a PN junction layer, the contact layer being formed on part of a surface of the cell layer which surface is on a side opposite to a light-receiving surface of the cell layer, and wherein the third electrode is formed on the contact layer.

A thin-film compound photovoltaic cell array comprises: a thin-film compound photovoltaic cell string including a plurality of the thin-film compound photovoltaic cells connected electrically; a front protective member disposed on a light receiving side of the thin-film compound photovoltaic cell string; and a back protective member disposed on a side opposite to the light receiving side of the thin-film compound photovoltaic cell string.

### Advantageous Effects of Invention

The thin-film compound photovoltaic cell and the thin-film film photovoltaic cell array provided by the present invention have the above-described structures and allow light to be transmitted to the side opposite to their light-receiving surface.

### BRIEF DESCRIPTION OF DRAWINGS

FIGS. 1(a) and 1(b) are schematic cross-sectional views of a compound photovoltaic cell in embodiment 1, FIG. 1(a) being a schematic plan view when the compound photovoltaic cell is viewed from its front side, FIG. 1(b) being a schematic plan view when the compound photovoltaic cell is viewed from its back side.

FIGS. 2(a) and 2(b) are schematic cross-sectional views of the compound photovoltaic cell in embodiment 1, FIG. 2(a) being a cross-sectional view taken along line A-A in FIG. 1(a), FIG. 2(b) being a cross-sectional view taken along line B-B in FIG. 1(a).

FIGS. 3(a) and 3(b) are schematic cross-sectional views of a compound photovoltaic cell in embodiment 2, FIG. 3(a) being a schematic plan view when the compound photovoltaic cell is viewed from its front side, FIG. 3(b) being a schematic plan view when the compound photovoltaic cell is viewed from its back side.

FIGS. 4(a) and 4(b) are schematic cross-sectional views of the compound photovoltaic cell in embodiment 2, FIG. 4(a) being a cross-sectional view taken along line A-A in FIG. 3(a), FIG. 4(b) being a cross-sectional view taken along line B-B in FIG. 3(a).

FIGS. 5(a) and 5(b) are schematic cross-sectional views of a compound photovoltaic cell in embodiment 3, FIG. 5(a) being a schematic plan view when the compound photovoltaic cell is viewed from its front side, FIG. 5(b) being a schematic plan view when the compound photovoltaic cell is viewed from its back side.

FIGS. 6(a) and 6(b) are schematic cross-sectional views of the compound photovoltaic cell in embodiment 3, FIG. 6(a) being a cross-sectional view taken along line A-A in FIG. 5(a), FIG. 6(b) being a cross-sectional view taken along line B-B in FIG. 5(a).

FIG. 7 is a schematic cross-sectional view illustrating part of a manufacturing process in an example of a thin-film compound photovoltaic cell manufacturing method in embodiment 4.

FIG. 8 is a schematic cross-sectional view illustrating another part of the manufacturing process in the example of the thin-film compound photovoltaic cell manufacturing method in embodiment 4.

FIG. 9 is a schematic cross-sectional view illustrating another part of the manufacturing process in the example of the thin-film compound photovoltaic cell manufacturing method in embodiment 4.

FIG. 10 is a schematic cross-sectional view illustrating another: part of the manufacturing process in the example of the thin-film compound photovoltaic cell manufacturing method in embodiment 4.

FIG. 11 is a schematic cross-sectional view illustrating another part of the manufacturing process in the example of the thin-film compound photovoltaic cell manufacturing method in embodiment 4.

FIG. 12 is a schematic cross-sectional view illustrating another part of the manufacturing process in the example of the thin-film compound photovoltaic cell manufacturing method in embodiment 4.

FIG. 13 is a schematic cross-sectional view illustrating another part of the manufacturing process in the example of the thin-film compound photovoltaic cell manufacturing method in embodiment 4.

FIG. 14 is a schematic cross-sectional view illustrating another part of the manufacturing process in the example of the thin-film compound photovoltaic cell manufacturing method in embodiment 4.

FIG. 15 is a schematic cross-sectional view of a thin-film compound photovoltaic cell array in embodiment 5.

FIG. 16 is a schematic cross-sectional view of a thin-film compound photovoltaic cell array in embodiment 6.

FIG. 17 is a schematic cross-sectional view of another structure of the thin-film compound photovoltaic cell array in embodiment 6.

### DESCRIPTION OF EMBODIMENTS

Embodiments of the present invention will next be described with reference to the drawings. In the drawings in the embodiments, the same reference numerals designate the same or corresponding parts. Relations between dimensions such as length, width, thickness, and depth in each drawing are appropriately changed for clarification and simplification of the drawing and do not represent actual dimensional relations. A light receiving side may be referred to as a front side, and the side opposite to the light receiving side may be referred to as a back side.

### Embodiment 1

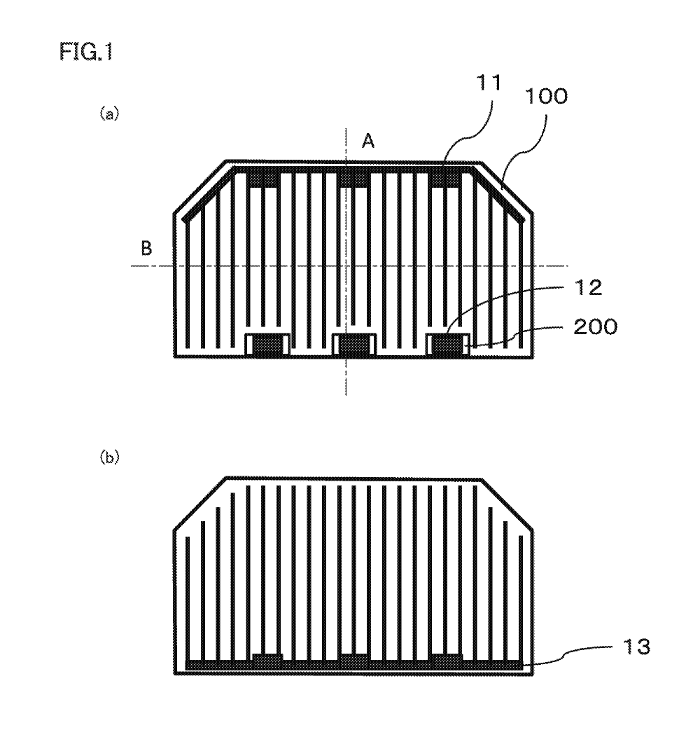

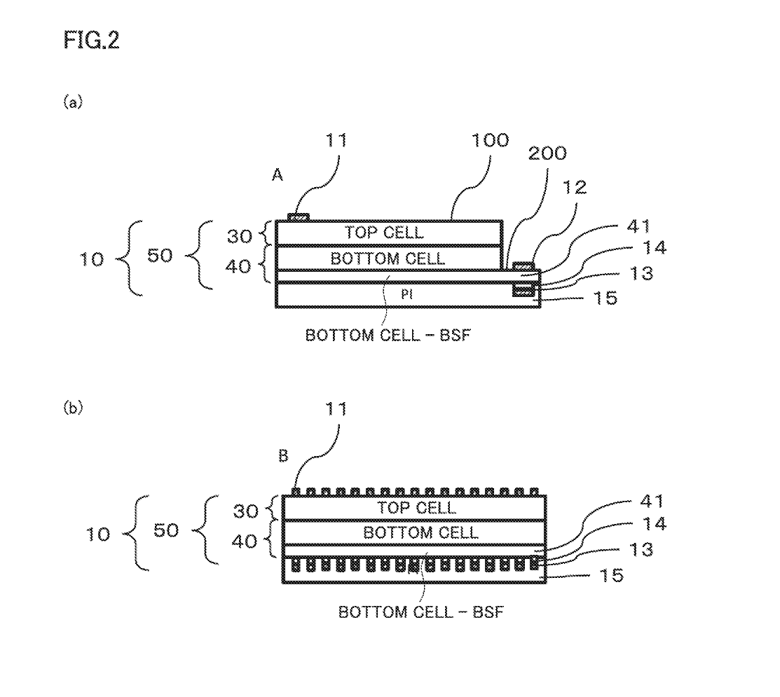

FIGS. 1 and 2 show schematic illustrations of a compound photovoltaic cell in embodiment 1 that is an example of the thin-film compound photovoltaic cell of the present invention. FIG. 1(a) is a schematic plan view when the compound photovoltaic cell is viewed from its front side, and FIG. 1(b) is a schematic plan view when the compound photovoltaic cell is viewed from its back side. FIG. 2(a) is a cross-sectional view taken along line A-A in FIG. 1(a), and FIG. 2(b) is cross-sectional view taken along line B-B in FIG. 1(a).

As shown in FIGS. 1 and 2, the thin-film compound photovoltaic cell in embodiment 1 includes a cell body 10 and a resin film 15 formed on the side opposite to the light receiving side of the cell body 10. The cell body 10 includes: a photovoltaic cell stack 50; a first electrode 11 having a first polarity; a second electrode 12 having a second polarity; and a third electrode 13 having the second polarity. The first electrode 11 is formed on part of a first surface 100 of the photovoltaic cell stack 50 that is on the light receiving side. The second electrode 12 is formed on a second surface 200 of the photovoltaic cell stack 50 that is on the light receiving side and differs from the first surface 100. The third electrode 13 is formed on part of a surface of the photovoltaic cell stack 50 that is on the side opposite to the light receiving side. The photovoltaic cell stack 50 includes a plurality of compound semiconductor layers. Specifically, the photovoltaic cell stack 50 includes: cell layers each including a PN junction layer; and a contact layer 14 formed on part of a surface of one of the cell layers which surface is opposite to the light-receiving surface.

The photovoltaic cell stack 50 in embodiment 1 includes, as the cell layers, a top cell 30 and a bottom cell 40. The top cell 30 is formed on the light-receiving surface side of the bottom cell 40. The bandgap (first bandgap) of a photoelectric conversion layer formed in the top cell 30 is larger than the bandgap (second bandgap) of a photoelectric conversion layer formed in the bottom cell 40. Each of the top cell 30 and the bottom cell 40 includes a window layer, a base layer, an emitter layer, and a back surface field layer (BSF layer). By joining the base layer and the emitter layer, a PN junction is formed. Preferably, the top cell 30 and the bottom cell 40 are formed of GaAs-based compounds, and the base layer and the emitter layer forming a PN junction layer are formed of GaAs-based compound semiconductors. For example, the PN junction layer of the top cell 30 is InGaP, and the PN junction layer of the bottom cell 40 is GaAs. The bottom cell 40 is composed of a BSF layer 41 formed of p-type InGaP, a base layer formed of p-type GaAs, an emitter layer formed of n-type GaAs, and a window layer formed of n-type InGaP that are sequentially stacked from the back side. A tunnel junction layer may be disposed between the top cell 30 and the bottom cell 40. For example, the tunnel junction layer includes an n+type InGaP layer and a p+type AlGaAs layer that are sequentially stacked from the bottom cell 40 side. The top cell 30 is composed of a BSF layer formed of p-type AlInP, a base layer formed of p-type InGaP, an emitter layer formed of n-type InGaP, and a window layer formed of n-type AlInP that are sequentially stacked from the bottom cell 40 side. A contact layer may be formed on the light receiving side of the window layer of the top cell 30 in regions in which the first electrode 11 is formed. This contact layer is, for example, n-type GaAs. An antireflection coat may be formed on the window layer except for the regions on which the first electrode 11 is formed. The antireflection coat is, for example, Al₂O₃/TiO₂.

The photovoltaic cell stack 50 has, on the light receiving side, the first surface 100 and the second surface 200 different from the first surface 100, and the first surface 100 and the second surface 200 are surfaces of different layers. For example, the first surface 100 is a surface of the top cell 30, and the second surface 200 is a surface of the BSF layer 41 of the bottom cell 40.

The first electrode 11 is formed on part of the first surface, and the second electrode 12 is formed on the second surface. The polarity of the first electrode 11 differs from the polarity of the second electrode 12. In embodiment 1, the first electrode 11 is formed on the light receiving side of the top cell 30 and is formed into a comb shape as shown in FIG. 1(a). The first electrode 11 and the second electrode 12 are output electrodes to which wiring lines are to be connected. The first electrode 11 contains metal and is, for example, a stack of AuGe/Ni/Au/Ag. The second electrode 12 contains metal and is, for example, a stack of Au/Ag.

The polarity of the third electrode 13 is the same as the polarity of the second electrode and is formed on the contact layer 14 formed on part of the back surface of the cell layer 40. In embodiment 1, the third electrode 13 is formed into a comb shape as shown in FIG. 1(b). The third electrode 13 is an electrode for collecting electric current generated in the cell layers and has a reduced electrical resistance. The third electrode 13 contains metal and is, for example, a stack of Au/Ag. The third electrode 13 may be disposed in regions corresponding to the first electrode 11. By aligning the third electrode 13 with the first electrode, regions from which light transmitted through the photovoltaic cell stack 50 is emitted can match light receiving regions of the photovoltaic cell stack 50.

The contact layer 14 is formed on part of the back surface of the cell layer 40. In other words, regions in which no contact layer 14 is disposed are formed on the back surface of the cell layer 40. The regions in which no contact layer 14 is disposed are not influenced by light absorption by the contact layer 14. Therefore, when not only the third electrode 13 but also the contact layer 14 is formed on part of the back surface of the photovoltaic cell stack 50, light can easily be transmitted to the back surface. In embodiment 1, the contact layer 14 is formed into a comb shape on the BSF layer 41 of the bottom cell. The contact layer 14 is, for example, GaAs.

The cell body 10 includes the photovoltaic cell stack 50, the first electrode 11, the second electrode 12, and the third electrode 13. The resin film 15 is formed on the back side of the cell body 10.

The resin film 15 is a support member formed on the back side of the cell body 10. The resin film 15 prevents the photovoltaic cell layer 50 from easily cracking, and the mechanical strength of the compound photovoltaic cell is thereby improved. Preferably, the resin film 15 is flexible. The material used for the resin film 15 may be, for example, polyimide (PI). The thickness of the resin film 15 may be, for example, about 5 to about 20 μm. The resin film 15 is light transmittable and can transmit at least light of a wavelength that contributes to power generation of the cell body 10 or another photovoltaic cell. When an additional photovoltaic cell is disposed on the back side of the thin-film compound photovoltaic cell in embodiment 1, it is only necessary that the resin film 15 can transmit at least light having an absorption wavelength of the photovoltaic cell disposed on the back side. The resin film 15 in embodiment 1 is flexible polyimide (PI).

As described above, in the thin-film compound photovoltaic cell in embodiment 1, the third electrode 13 is formed on part of the back surface of the cell layer 40, and the insulating film 15 disposed on the back side of the cell body 10 is light transmittable, so that light can be transmitted to the side opposite to the light-receiving surface. Since also the contact layer 14 is formed on only part of the back side of the cell layer 40, improved light transmitting properties are obtained. Therefore, the thin-film compound photovoltaic cell in embodiment 1 can be used as a photovoltaic cell on the light incident side of a mechanically stacked photovoltaic cell. Since light enters the photovoltaic cell stack 50 also from the back side, the thin-film compound photovoltaic cell in embodiment 1 can also be used as a double-sided light receiving cell.

### (Other Structures)

The second surface 200 may be a surface of the contact layer 14. In this case, the second electrode 12 is formed on the light receiving surface of the contact layer 14.

It will be appreciated that the materials in the above embodiment are merely examples and not limitations.

The stacking structure of the photovoltaic cell stack is not limited to the above-described structure, and it is only necessary that at least one cell layer having a PN junction layer be provided.

### Embodiment 2

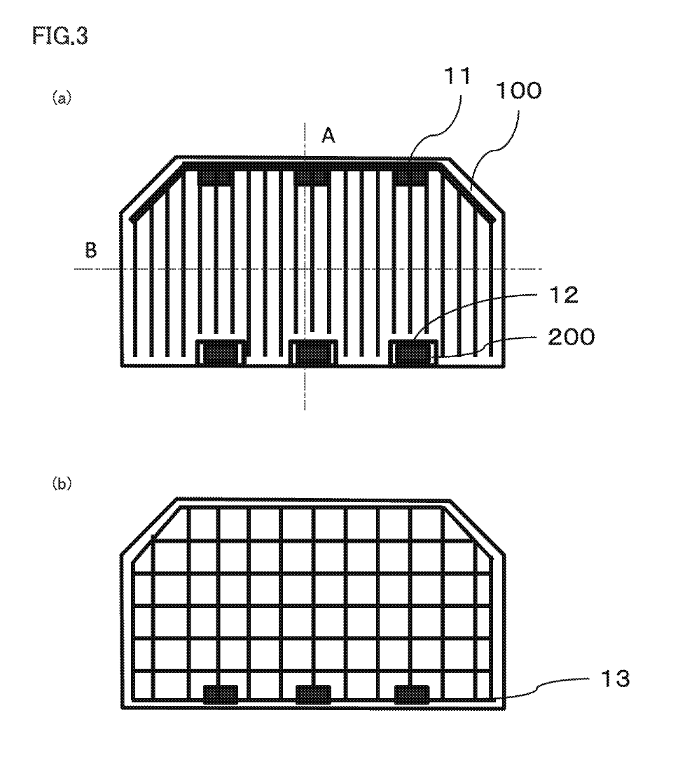

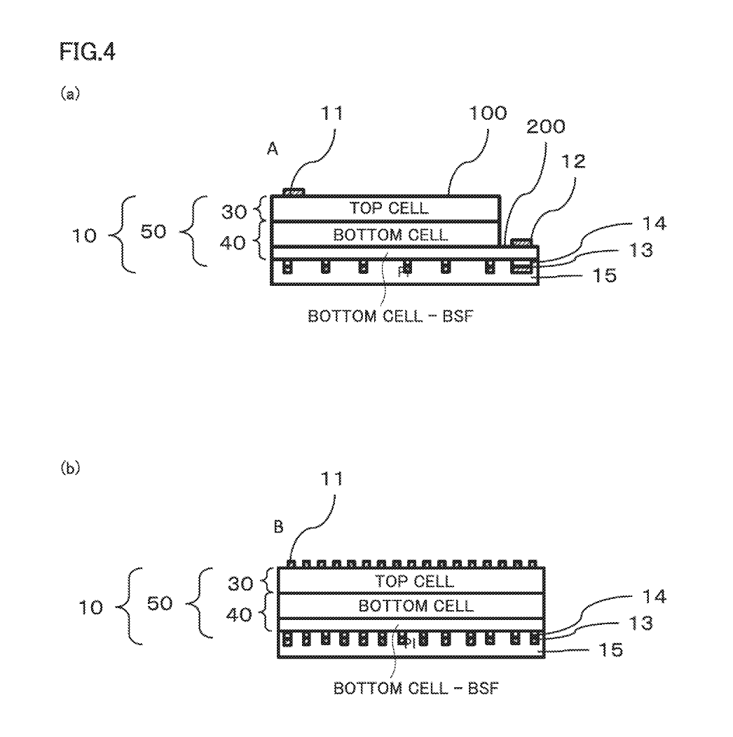

FIGS. 3 and 4 show illustrations of a compound photovoltaic cell in embodiment 1 that is an example of the thin-film compound photovoltaic cell of the present invention. FIG. 3(a) is a schematic plan view when the compound photovoltaic cell is viewed from its front side, and FIG. 3(b) is a schematic plan view when the compound photovoltaic cell is viewed from its back side. FIG. 4(a) is a cross-sectional view taken along line A-A in FIG. 3(a), and FIG. 4(b) is cross-sectional view taken along line B-B in FIG. 3(a).

The thin-film compound photovoltaic cell in embodiment 2 differs from the thin-film compound photovoltaic cell in embodiment 1 in the shapes of the contact layer 14 and the third electrode 13. The rest of the structure is the same as that of the thin-film compound photovoltaic cell in embodiment 1.

The contact layer 14 and the third electrode 13 in embodiment 2 each have a lattice shape as shown in FIG. 3(b). The contact layer 14 and the third electrode 13 are formed on part of the back surface of the cell layer 40, and regions in which no contact layer 14 is disposed are present on the back surface of the cell layer 40. Since light can be transmitted to the back side, the thin-film compound photovoltaic cell in embodiment 2 can be used as a photovoltaic cell on the light incident side of a mechanically stacked photovoltaic cell. Since electric power can be generated using light received from the back side, the thin-film compound photovoltaic cell can also be used as a double-sided light receiving photovoltaic cell.

### Embodiment 3

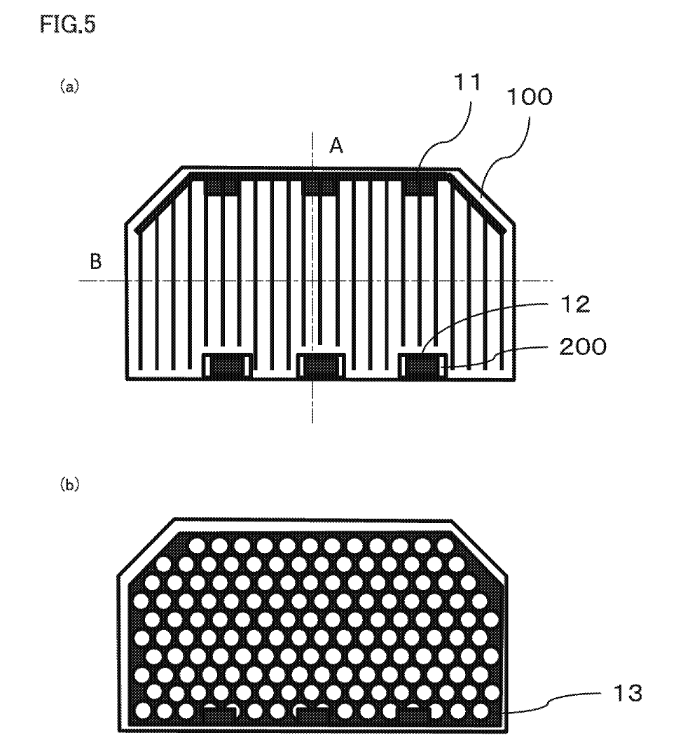

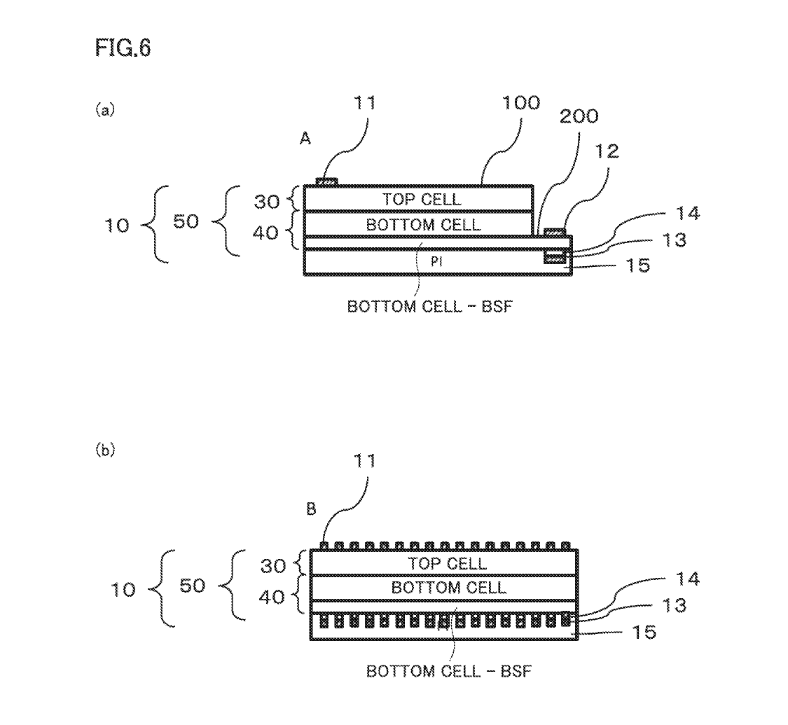

FIGS. 5 and 6 show schematic illustrations of a compound photovoltaic cell in embodiment 3 that is an example of the thin-film compound photovoltaic cell of the present invention. FIG. 5(a) is a schematic plan view when the compound photovoltaic cell is viewed from its front side, and FIG. 5(b) is a schematic plan view when the compound photovoltaic cell is viewed from its back side. FIG. 6(a) is a cross-sectional view taken along line A-A in FIG. 5(a), and FIG. 6(b) is cross-sectional view taken along B-B in FIG. 5(a).

The thin-film compound photovoltaic cell in embodiment 3 differs from the thin-film compound photovoltaic cell in embodiment 1 in the shapes of the contact layer 14 and the third electrode 13. The rest of the structure is the same as that of the thin-film compound photovoltaic cell in embodiment 1.

The contact layer 14 and the third electrode 13 in embodiment 3 will be described. As shown in FIG. 5(b), the contact layer 14 and the third electrode 13 are each formed into a mesh shape on part of the back surface of the cell layer 40. The back surface of the cell layer 40 is dotted with regions in which the contact layer 14 and the third electrode 13 are not disposed. Therefore, since light can be transmitted to the back side, the thin-film compound photovoltaic cell in embodiment 2 can be used as a photovoltaic cell on the light incident side of a mechanically stacked photovoltaic cell. Since electric power can be generated using light received from the back side, the thin-film compound photovoltaic cell can also be used as a double-sided light receiving photovoltaic cell.

### Embodiment 4

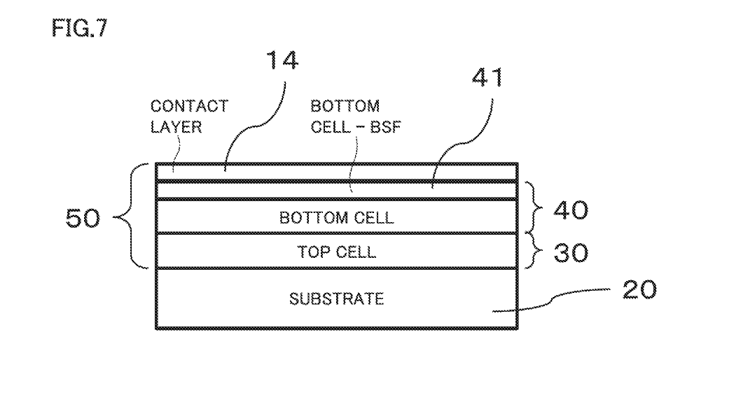

Embodiment 4 is an example of a method for manufacturing the thin-film compound photovoltaic cell of the present invention, and this method can produce the thin-film compound photovoltaic cells in embodiments 1 to 3. Referring next to FIGS. 7 to 14, the thin-film compound photovoltaic cell production method in embodiment 4 will be described.

### (Step of Forming Photovoltaic Cell Stack)

First, as shown in FIG. 7, a plurality of compound semiconductor layers are stacked on a semiconductor substrate 20 to thereby form a photovoltaic cell stack 50. The photovoltaic cell stack 50 includes: cell layers (the top cell 30 and the bottom cell 40) each having a PN junction layer; and a contact layer 14 stacked on the cell layers.

Examples of the material of the semiconductor substrate 20 include germanium (Ge) and gallium arsenide (GaAs). In embodiment 4, the semiconductor substrate 20 (GaAs substrate) is placed in an MOCVD (Metal Organic Chemical Vapor Deposition) apparatus. A GaAs layer serving as a buffer layer for optimizing a growth surface, an etching stop layer formed of n-type InGaP that is an etching stop layer selectively etchable with respect to GaAs, and n-type GaAs forming a contact layer are epitaxially grown in this order on the GaAs substrate by the MOCVD method.

Next, n-type AlInP forming the window layer of the top cell 30, n-type InGaP forming the emitter layer, p-type InGaP forming the base layer, and p-type AlInP forming the BSF layer are epitaxially grown in this order by the MOCVD method.

Next, a p+type AlGaAs layer is epitaxially grown on the top cell 30 by the MOCVD method, and then a p+type AlGaAs layer and n+type InGaP that form a tunnel junction layer are epitaxially grown in this order by the MOCVD method.

Next, n-type InGaP forming the window layer of the bottom cell 40, n-type GaAs forming the emitter layer, p-type GaAs forming the base layer, and p-type InGaP forming the BSF layer 41 are epitaxially grown in this order on the tunnel junction layer by the MOCVD method.

To form GaAs, AsH₃ (arsine) and TMG (trimethylgallium) may be used. To form InGaP, TMI (trimethylindium), TMG, and PH₃ (phosphine) may be used.

Next, p-type GaAs 14 forming the contact layer is epitaxially grown on the bottom cell 40 by the MOCVD method.

To form GaAs, AsH₃ (arsine) and TMG (trimethylgallium) may be used. To form InGaP, TMI (trimethylindium), TMG, and PH₃ (phosphine) may be used.

### (Step of Patterning Contact Layer)

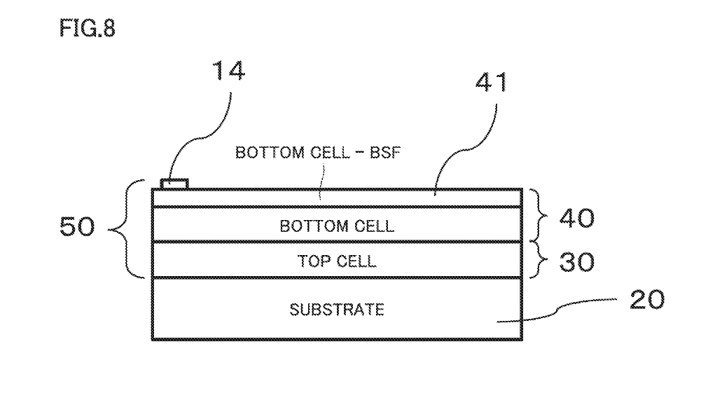

Next, as shown in FIG. 8, the contact layer 14 is patterned to form regions in which the contact layer 14 is not disposed on the bottom cell 40. Specifically, a resist pattern is formed on the contact layer 14 by photolithography, and then etching is performed to remove the contact layer from regions with no resist pattern to thereby pattern the contact layer 14.

### (Step of Forming Third Electrode)

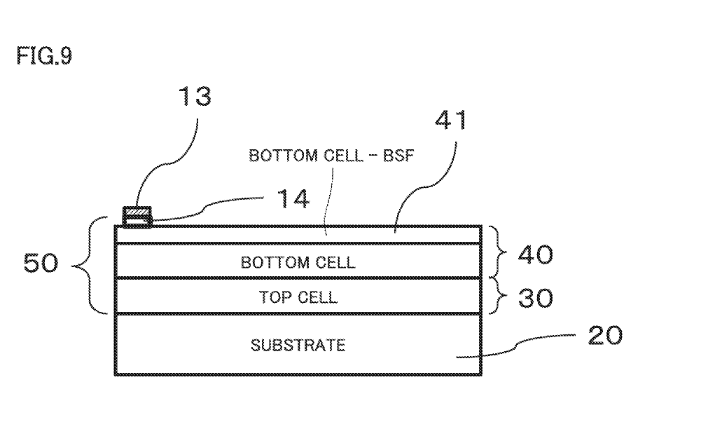

Then, as shown in FIG. 9, the third electrode 13 is formed on the contact layer 14. Specifically, a resist pattern is again formed on the contact layer 14 by photolithography, and a stack of Au/Ag is vapor-deposited using a vapor deposition apparatus and then lifted-off, whereby the third electrode 13 can be formed on the contact layer 14. Then the third electrode is subjected to heat treatment, and the contact resistance between the third electrode and the contact layer can thereby be reduced. The third electrode 13 is patterned similarly to the contact layer 14, and regions in which the third electrode 13 is not disposed are formed on the bottom cell 40.

### (Step of Forming Resin Film)

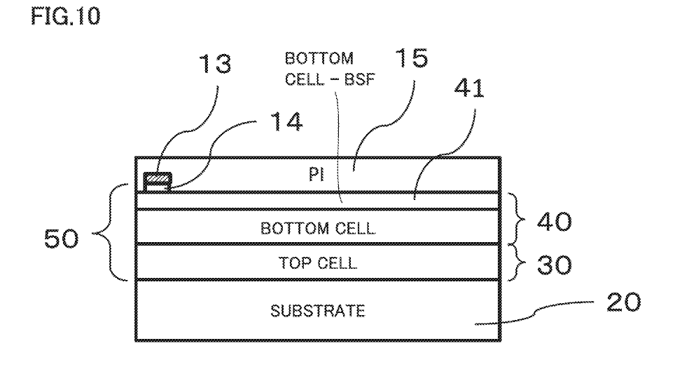

Next, as shown in FIG. 10, the resin film 15 is formed on the bottom cell 40 and the third electrode 13. The resin film 15 is, for example, flexible polyimide (PI) and is formed by applying a polyimide solution by, for example, a spin coating method and then subjecting the polyimide solution to heat treatment for imidization.

### (Step of Removing Semiconductor Substrate)

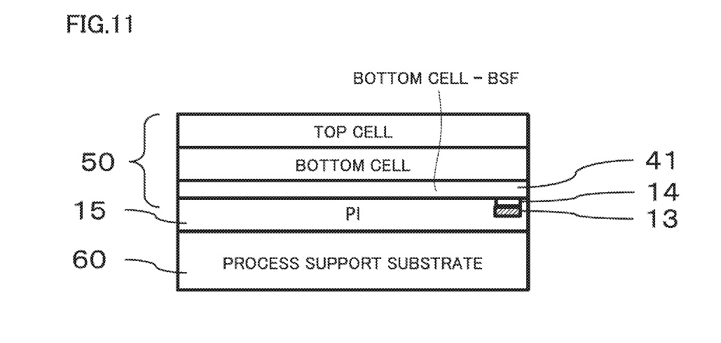

Next, as shown in FIG. 11, a support substrate 60 (process support substrate) is applied to the resin film 15, and the GaAs substrate is removed by etching. The support substrate 60 used may be, for example, a PET film to which an adhesive whose adhesion can be reduced by UV irradiation adheres or a thermally foamed film to which an adhesive whose adhesion can be reduced by application of heat adheres.

### (Step of Forming First Electrode)

Next, the GaAs buffer layer is etched with an aqueous alkali solution, and the etching stop layer formed of n-type InGaP is etched with an aqueous acid solution (these are not shown). Then a resist pattern is formed on the n-type GaAs contact layer of the top cell 30 by photolithography, and etching with an aqueous alkali solution is performed to remove the n-type GaAs contact layer from regions with no resist pattern. Then a resist pattern is again formed on the surface of the remaining n-type GaAs contact layer by photolithography, and the first electrode 11 formed from a stack of AuGe/Ni/Au/Ag is formed using a vapor deposition apparatus. Then the first electrode is subjected to heat treatment, and the contact resistance between the first electrode and a compound semiconductor layer in contact with the first electrode can thereby be reduced. In this manner, the first electrode 11 is formed on part of the first surface 100 that is the light receiving surface of the top cell 30.

### (Step of Forming Second Surface)

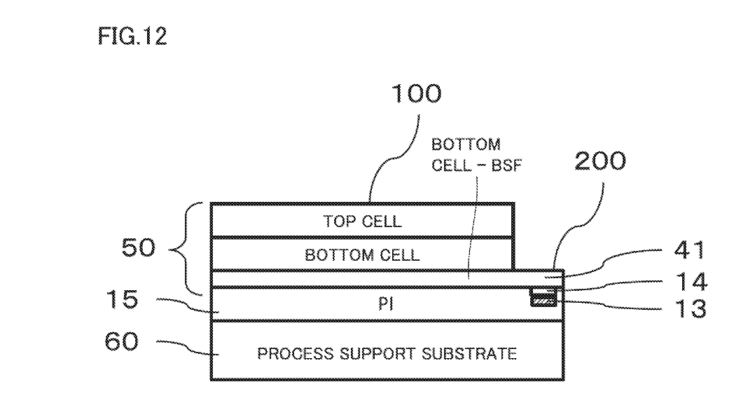

Next, as shown in FIG. 12, a resist pattern is formed by photolithography on the window layer of the top cell 30 that is formed of n-type AlGaP. Then etching is performed to remove the window layer and layers therebelow from regions with no resist pattern so that the surface of p-type InGaP forming the BSF layer 41 of the bottom cell is exposed. In this manner, the second surface 200 that is the light receiving surface of the back surface field layer 41 of the bottom cell is formed.

### (Step of Forming Second Electrode)

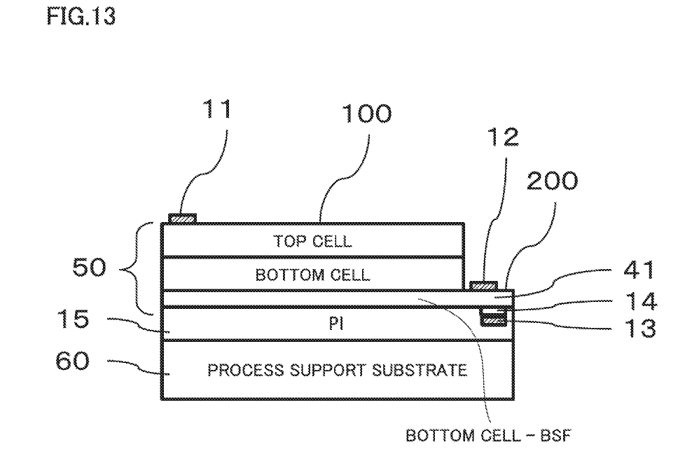

Then, as shown in FIG. 13, a resist pattern is again formed by photolithography on the surface of the p-type InGaP which is the remaining BSF layer 41 of the bottom cell, and the second electrode 12 formed from a stack of Au/Ag is formed using a vapor deposition apparatus. The second electrode 12 is thereby formed on the second surface 200.

Next, an antireflection coat (not shown) formed of Al₂O₃/TiO₂ is formed on the top cell 30 by a sputtering method.

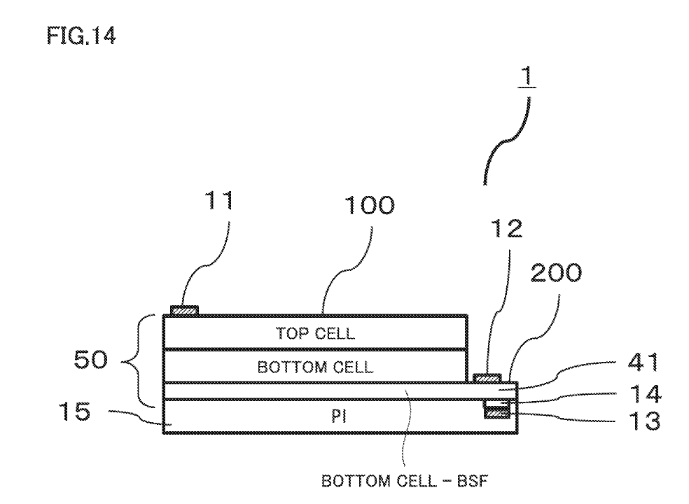

Next, the process support substrate 60 is detached. Specifically, the adhesion of the adhesive adhering to the process support substrate 60 is reduced to peel the process support substrate 60 from the resin film 15. For example, the process support substrate 60 is irradiated with UV light to reduce the adhesion of the adhesive adhering to the process support substrate 60, and then the process support substrate 60 is peeled from the resin film 15. A compound photovoltaic cell 1 having the structure shown in FIG. 14 is thereby obtained. Since the semiconductor substrate 20 has been removed and the resin film 15 is flexible, the compound photovoltaic cell 1 is a flexible photovoltaic cell.

### (Other Structures)

A sacrificial layer may be formed between the semiconductor substrate 20 and the photovoltaic cell stack 50. For example, a buffer layer, a sacrificial layer, an etching stop layer, and a first contact layer are formed on the semiconductor substrate by crystal growth. The sacrificial layer is thereby formed between the semiconductor substrate 20 and the top cell 30.

The sacrificial layer used can be formed of any semiconductor so long as it is easily etched. The “sacrificial layer” is disposed between the semiconductor substrate 20 and the photovoltaic cell stack 50. The sacrificial layer is provided in order to separate the semiconductor substrate from the photovoltaic cell stack by removing the sacrificial layer by, for example, etching. The semiconductor used for the sacrificial layer is, for example, AlAs. When the sacrificial layer used is formed of AlAs, it is preferable that the etchant used to etch the sacrificial layer is, for example, hydrochloric acid or an aqueous hydrofluoric acid solution prepared by mixing hydrofluoric acid and water at a ratio of 1 to 10. By removing the sacrificial layer by etching, the semiconductor substrate 20 is separated from the photovoltaic cell stack 50.

The etching stop layer is used to protect the photovoltaic cell stack 50 and the contact layer such that they are not exposed to the etchant when the sacrificial layer is etched. One example of the material forming the etching stop layer is InGaP.

The above-described method including producing the sacrificial layer between the semiconductor substrate and the photovoltaic cell layer and removing the sacrificial layer using the etchant to thereby separate the semiconductor substrate from the photovoltaic cell layer is referred to as epitaxial lift-off. Since the semiconductor substrate is not removed by etching but is separated, the semiconductor substrate can be reused.

In the step of forming the second surface, etching may be performed to remove the window layer and layers therebelow from regions with no resist pattern so that the contact layer 14 is exposed. The second surface 200 that is the light receiving surface of the contact layer 14 may be formed in the manner described above. In this case, in the step of forming the second electrode, the second electrode is formed on the second surface 200 that is the light receiving surface of the contact layer 14.

As described above, in the present embodiment, a thin-film compound photovoltaic cell in which regions with no contact layer and no electrode disposed are present on the back side can be manufactured.

Therefore, in the present embodiment, a thin-film compound photovoltaic cell in which light can be transmitted to the back side can be manufactured. Moreover, a double-sided light receiving thin-film compound photovoltaic cell that can generate electric power using light received from the back side can be manufactured.

It will be appreciated that the materials in the above embodiment are merely examples and not limitations.

The stacking structure on the semiconductor substrate 20 is not limited to the above-described structure, and it is only necessary that at least one cell layer having a PN junction layer is provided.

### Embodiment 5

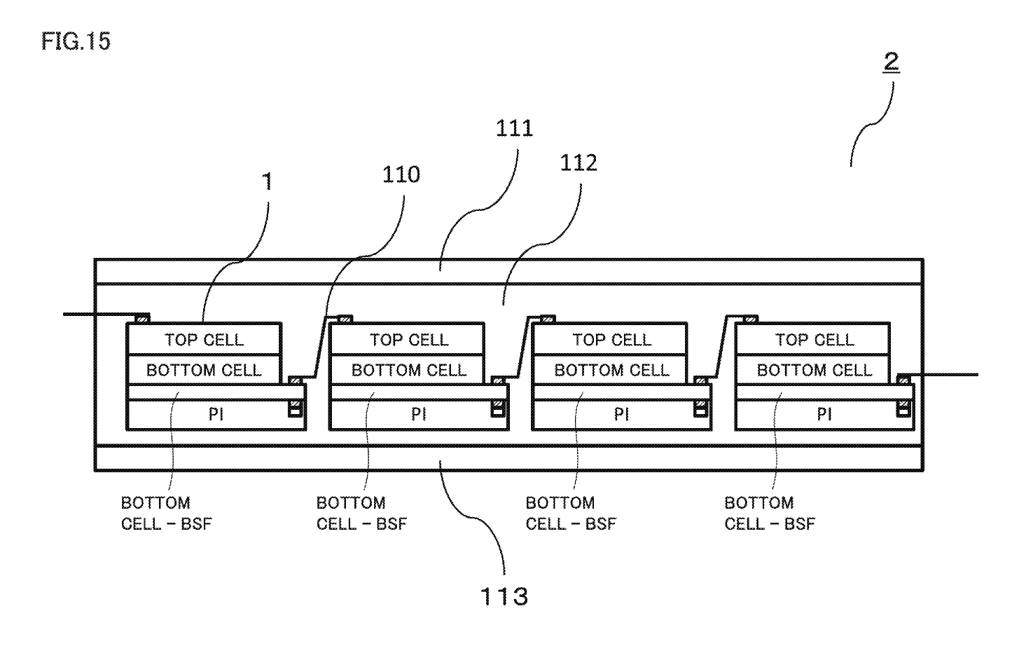

FIG. 15 is a schematic cross-sectional view of a compound photovoltaic cell array in embodiment 5 that is an example of the thin-film compound photovoltaic cell array of the present invention.

The thin-film compound photovoltaic cell array 2 in embodiment 5 includes: a thin-film compound photovoltaic cell string including a plurality of thin-film compound photovoltaic cells 1 electrically connected to each other; a front protective member 111 disposed on the light receiving side; and a back protective member 112 disposed on the back side. The thin-film compound photovoltaic cells and a method for manufacturing the same will be described.

### (Step of Forming Thin-Film Compound Photovoltaic Cell String)

Each of the thin-film compound photovoltaic cells 1 is a thin-film compound photovoltaic cell in which regions with no contact layer and no electrode are present on the back side of the cell layers, and the thin-film compound photovoltaic cell in any of the above embodiments may be used.

The plurality of thin-film compound photovoltaic cells 1 are electrically connected to each other through wiring members 110 to thereby form the thin-film compound photovoltaic cell string. As shown in FIG. 15, in embodiment 5, the first electrode of each thin-film compound photovoltaic cell 1 is electrically connected to the second electrode of an adjacent one of the thin-film compound photovoltaic cells 1 through a wiring member 110 such as a metal ribbon, and the plurality of thin-film compound photovoltaic cells 1 are thereby connected in series.

As shown in FIG. 14, in each thin-film compound photovoltaic cell 1, the first electrode 11 and the second electrode 12 are disposed on the front side. Therefore, wiring lines can easily be connected to the electrodes on the front side.

### (Step of Disposing Front Protective Member and Back Protective Member)

The front protective member 111 is disposed on the light receiving side of the thin-film compound photovoltaic cell string, and the back protective member 113 is disposed on the side opposite to the light receiving side. These protective members 111 and 113 are laminated with a transparent resin 112 as an adhesive. Each of the front protective member 111 and the back protective member 113 used may be a transparent film or glass, and they are preferably flexible. The transparent resin 112 used may be silicone. When the front protective member and the back protective member are flexible, also the thin-film compound photovoltaic cell array 2 is flexible.

As described above, the thin-film compound photovoltaic cell array 2 uses the thin-film compound photovoltaic cells 1 in which light is transmitted to the back side. Since light is transmitted to the back side of the thin-film compound photovoltaic cell array 2, an additional photovoltaic cell module can be stacked on the back side and used in combination. Since the thin-film compound photovoltaic cell array 2 can generate electric power using light received from the back side, the thin-film compound photovoltaic cell array 2 can be used as a double-sided light receiving thin-film compound photovoltaic cell array.

### Embodiment 6

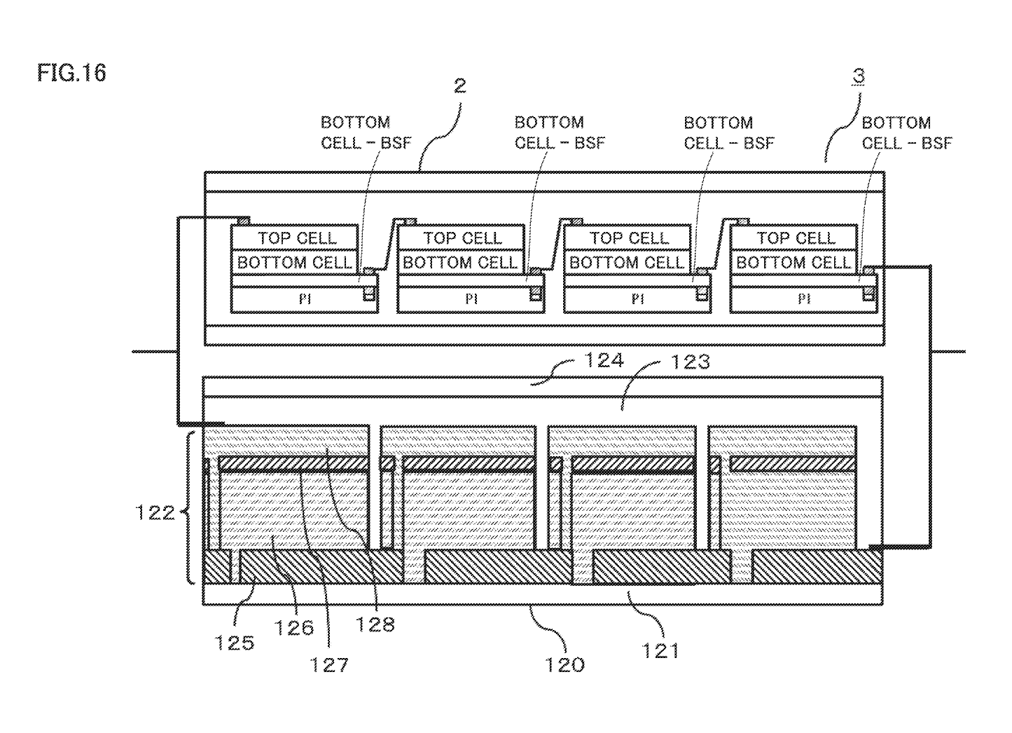

FIG. 16 shows a schematic cross-sectional view of a compound photovoltaic cell array in embodiment 6 that is an example of the thin-film compound photovoltaic cell array of the present invention.

As shown in FIG. 16, the thin-film compound photovoltaic cell array 3 in embodiment 6 includes the thin-film compound photovoltaic cell array 2 and an additional photovoltaic cell module 120 disposed on the side opposite to the light receiving side of the thin-film compound photovoltaic cell array 2. The thin-film compound photovoltaic cell array 2 is electrically connected to the photovoltaic cell module 120. In FIG. 16, the thin-film compound photovoltaic cell array 2 and the additional photovoltaic cell module 120 are connected in parallel to each other. When they are connected in parallel, it is preferable that the voltage of the thin-film compound photovoltaic cell array 2 is equal to the voltage of the photovoltaic cell module 120. Each of the thin-film compound photovoltaic cell array 2 and the photovoltaic cell module 120 includes a plurality of photovoltaic cells connected in series. Therefore, by adjusting the numbers of photovoltaic cells, the thin-film compound photovoltaic cell array 2 and the photovoltaic cell module 120 can have the same voltage.

The photovoltaic cell module 120 is a crystalline Si photovoltaic cell module, a Ge photovoltaic cell module, a CIGS-based photovoltaic cell module, etc. These may be used in combination. For example, a crystalline Si photovoltaic cell module may be stacked on a Ge photovoltaic cell module.

In embodiment 6, the additional photovoltaic cell module 120 disposed on the back side of the photovoltaic cell array 2 is a CIGS-based photovoltaic cell module.

As shown in FIG. 16, the photovoltaic cell module 120 includes a substrate 121, a photovoltaic cell layer 122, an adhesive 123, and a front member 124. The photovoltaic cell layer 122 includes a lower electrode layer 125, a light absorbing layer 126, a high-resistance buffer layer 127, and an upper electrode layer 128 that are stacked in this order on the substrate 121.

Each of the substrate 121 and the front member 124 used may be a transparent film or glass and is preferably flexible. The adhesive 123 is a transparent resin, and silicone may be used. In embodiment 6, since the substrate 121 and the front member 124 are flexible, the photovoltaic cell module 120 is flexible.

In the photovoltaic cell layer 122, the lower electrode layer 125 may be, for example, Mo, and the light absorbing layer 126 may be CIGS containing copper, indium, gallium, and selenium. The high-resistance buffer layer 127 may be InS, ZnS, CdS, etc., and the upper electrode layer 128 may be ITO. In embodiment 6, the lower electrode layer 125 is Mo, and the light absorbing layer 126 is a stack of p-CuInGaSe and p-CuInGaSeS. The high-resistance buffer layer 127 is ZnOSOH, and the upper electrode layer 128 is ZnO.

As described above, since the photovoltaic cell module 120 is flexible, the thin-film compound photovoltaic cell array 3 is flexible and is suitable for a photovoltaic cell array for space use. Since the photovoltaic cell module 120 is a CIGS-based module, almost no deterioration due to electron beams occurs, and the thin-film compound photovoltaic cell array 2 provides protection from proton beams, so that radiation hardness that is important in the space environment is achieved.

Suppose that the voltage of the thin-film compound photovoltaic cell array 2 is equal to the voltage of the photovoltaic cell module 120. When the thin-film compound photovoltaic cell array 2 includes, for example, five 2.45 V thin-film compound photovoltaic cells connected in series, the voltage of the thin-film compound photovoltaic cell array 2 is 12.25 V. In this case, when the voltage of each cell of the photovoltaic cell module 120 is 0.65 V, 20 cells are connected in series. When thin-film photovoltaic cells such as CIGS-based photovoltaic cells are used, the number of cells connected in series can be easily adjusted.

### (Other Structures)

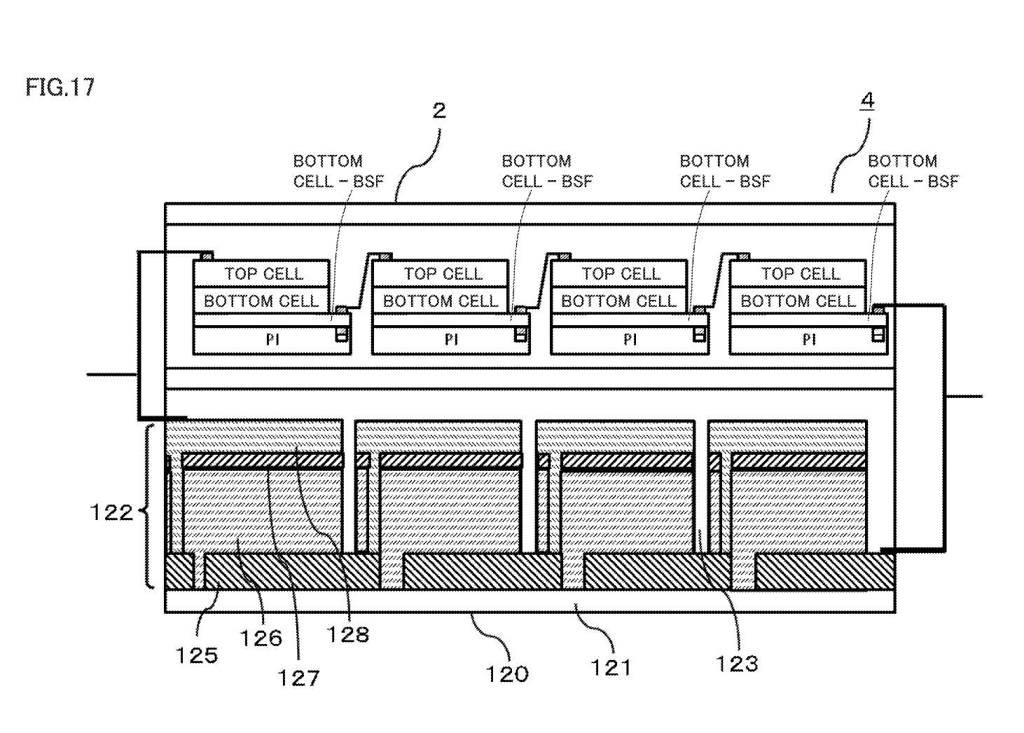

FIG. 17 shows a schematic cross-sectional view of another structure of the compound photovoltaic cell array in embodiment 6 that is an example of the thin-film compound photovoltaic cell array of the present invention.

As shown in FIG. 17, in the thin-film compound photovoltaic cell array 4, the thin-film compound photovoltaic cell array 2 is disposed on the photovoltaic cell layer 122 of the photovoltaic cell module 120 through the adhesive 123.

The thin-film compound photovoltaic cell array 4 is formed by laminating the photovoltaic cell layer 122 formed on the substrate 121 and the thin-film compound photovoltaic cell array 2 with the adhesive 123. In this case, the front member 124 in embodiment 6 can be omitted. Moreover, the thin-film compound photovoltaic cell array 2 can be easily integrated with the photovoltaic cell module 120.

It will be appreciated that the materials in the above embodiment are merely examples and not limitations.

The embodiments of the present invention have been described. It is originally intended that some features of the embodiments and Examples may be combined appropriately.

It should be understood that the embodiments disclosed herein are illustrative and nonrestrictive in every respect. The scope of the present invention is defined not by the preceding description but instead by the scope of the claims and is intended to include any modifications within the scope of the claims and meaning equivalent to the scope of the claims.

### REFERENCE SIGNS LIST

1 thin-film compound photovoltaic cell
2 thin-film compound photovoltaic cell array
10 cell body
11 first electrode
12 second electrode
13 third electrode
14 contact layer
15 resin film
20 semiconductor substrate
30 top cell
40 bottom cell
41 bottom cell BSF layer
50 photovoltaic cell stack
60 process support substrate
100 first surface
120 photovoltaic cell module
200 second surface

1. A thin-film compound photovoltaic cell comprising:
a cell body including
a photovoltaic cell stack including a plurality of compound semiconductor layers,
a first electrode that has a first polarity and is formed on part of a first surface of the photovoltaic cell stack, the first surface being on a light receiving side of the photovoltaic cell stack,
a second electrode that has a second polarity and is formed on a second surface of the photovoltaic cell stack, the second surface being on the light receiving side of the photovoltaic cell stack and being different from the first surface, and
a third electrode that has the second polarity and is formed on part of a surface of the photovoltaic cell stack which surface is on a side opposite to the light receiving side of the photovoltaic cell stack; and
a resin film formed on the cell body, the resin film being formed on a side opposite to a light receiving side of the cell body,
wherein the photovoltaic cell stack includes a cell layer and a contact layer, the cell layer including a PN junction layer, the contact layer being formed on part of a surface of the cell layer which surface is on a side opposite to a light-receiving surface of the cell layer, and
wherein the third electrode is formed on the contact layer.

2. The thin-film compound photovoltaic cell according to claim 1,
wherein the cell layer includes a window layer, a base layer, an emitter layer, a back surface field layer, and
wherein the second surface is a surface of the back surface field layer.

3. The thin-film compound photovoltaic cell according to claim 1,
wherein the second surface is a surface of the contact layer.

4. The thin-film compound photovoltaic cell according to claim 1,
wherein the PN junction layer is formed of GaAs-based compound semiconductors.

5. A thin-film compound photovoltaic cell array comprising:
a thin-film compound photovoltaic cell string including a plurality of the thin-film compound photovoltaic cells according to claim 1, the plurality of thin-film compound photovoltaic cells being electrically connected to each other;
a front protective member disposed on a light receiving side of the thin-film compound photovoltaic cell string; and
a back protective member disposed on a side opposite to the light receiving side of the thin-film compound photovoltaic cell string.

6. The thin-film compound photovoltaic cell array according to claim 5, further comprising
a photovoltaic cell module disposed on a side opposite to a light receiving side of the back protective member.

7. The thin-film compound photovoltaic cell array according to claim 6,
wherein the photovoltaic cell module is a CIGS-based photovoltaic cell module.

8. A method for manufacturing a thin-film compound photovoltaic cell, the method comprising the steps of:
stacking a plurality of compound semiconductor layers on a semiconductor substrate to thereby form a photovoltaic cell stack including a cell layer having a PN junction layer and a contact layer stacked on the cell layer;
patterning the contact layer;
forming a third electrode on the contact layer;
forming a resin film on the photovoltaic cell stack and the third electrode;
removing the semiconductor substrate;
forming a first electrode on part of a first surface of the photovoltaic cell stack which first surface has been formed in the step of removing the semiconductor substrate;
removing part of the photovoltaic cell stack to form a second surface on the photovoltaic cell stack; and
forming a second electrode on the second surface.

9. A method for manufacturing a thin-film compound photovoltaic cell array, the method comprising the steps of:
disposing a CIGS-based photovoltaic cell module on a side opposite to a light receiving side of the thin-film compound photovoltaic cell array according to claim 5; and
electrically connecting the thin-film compound photovoltaic cell array to the CIGS-based photovoltaic cell module.
